(19) United States
(12) Patent Application Publication
(10) Pub. No.: US 2025/0094829 A1
(43) Pub. Date: Mar. 20, 2025

(54) METHODS AND MECHANISMS FOR TRACE-BASED TRANSFER LEARNING

(71) Applicant: Applied Materials, Inc., Santa Clara, CA (US)

(72) Inventors: Fei Li, Houston, TX (US); Jimmy Iskandar, Fremont, CA (US); James Robert Moyne, Canton, MI (US)

(21) Appl. No.: 18/368,311

(22) Filed: Sep. 14, 2023

(51) Int. Cl. G06N 5/022

(52) U.S. Cl. CPC G06N 5/022

(57) ABSTRACT

An electronic device manufacturing system configured identify a machine-learning model trained to generate analytic or predictive data for a first substrate processing domain associated with a type of substrate processing system. The system is further configured to obtain first trace data pertaining to the first domain used to train the machine-learning model. The system is further configured to a transfer model for a second substrate processing domain associated with the type of substrate processing system. The transfer model is generated based on the first trace data pertaining to the first substrate processing domain and second trace data pertaining to the second substrate processing domain. Using the transfer model, at least one of the machine-learning model or current trace data associated with the second substrate processing domain is modified to enable the machine-learning model to generate analytic or predictive data associated with the second substrate processing domain.

### TECHNICAL FIELD

The present disclosure relates to electrical components, and, more particularly, to methods and mechanisms for trace-based transfer learning at a manufacturing system.

### BACKGROUND

Products can be produced by performing one or more manufacturing processes using manufacturing equipment. For example, semiconductor manufacturing equipment can be used to produce semiconductor devices (e.g., substrates) via semiconductor manufacturing processes. The manufacturing equipment can, according to a process recipe, deposit multiple layers of film on the surface of the substrate and can perform an etch process to form the intricate pattern in the deposited film. For example, the manufacturing equipment can perform a chemical vapor deposition (CVD) process to deposit alternative layers on the substrate. Etch process equipment can then be used to remove material from areas of a substrate through, e.g., chemical reaction and/or physical bombardment.

Sensors can be used to determine manufacturing parameters of the manufacturing equipment during the manufacturing processes and metrology equipment can be used to determine property data of the products that were produced by the manufacturing equipment, such as the overall thickness of the layers on the substrate. Using the manufacturing parameters and the property data, a machine-learning model can be trained to generate predictive metrology data using current input data (e.g., sensor data).

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In an aspect of the disclosure, an electronic device manufacturing system configured to identify a machine-learning model trained to generate analytic or predictive data for a first substrate processing domain associated with a type of substrate processing system. The system is further configured to obtain first trace data pertaining to the first substrate processing domain used to train the machine-learning model. The system is further configured to a transfer model for a second substrate processing domain associated with the type of substrate processing system. The transfer model is generated based on the first trace data pertaining to the first substrate processing domain and second trace data pertaining to the second substrate processing domain. Using the transfer model, at least one of the machine-learning model or current trace data associated with the second substrate processing domain is modified to enable the machine-learning model to generate analytic or predictive data associated with the second substrate processing domain.

In another aspect of the disclosure, an electronic device manufacturing system configured to provide, as input to a transfer model, current trace data pertaining to a target substrate processing domain. The transfer model is generated based on historical trace data pertaining to the target substrate processing domain and historical trace data pertaining to a source substrate processing domain. The source substrate processing domain and the target substrate processing domain are both associated with a type of substrate processing system. The system is further configured to obtain, from the transfer model, one or more first output values reflective of the current trace data modified by a set of offset values. The system is further configured to provide, to a machine-learning model trained to generate analytic or predictive data for the source substrate processing domain, the one or more first output values. The system is further configured to obtain, from the machine-learning model, one or more second output values reflecting analytic or predictive data pertaining to the target substrate processing domain.

In another aspect of the disclosure, an electronic device manufacturing system configured to retrain a machine-learning model using a transfer model. The transfer model is generated based on historical trace data pertaining to a target substrate processing domain and historical trace data pertaining to a source substrate processing domain. The machine-learning model is trained to generate analytic or predictive data for the source substrate processing domain. The system is further configured to provide, to the retrained machine-learning model, current trace data associated with the target substrate processing domain. The system is further configured to obtain one or more output values of the retrained machine-learning model reflecting analytic or predictive data associated with the target substrate processing domain.

A further aspect of the disclosure includes a method according to any aspect or implementation described herein.

A further aspect of the disclosure includes a non-transitory computer-readable storage medium comprising instructions that, when executed by a processing device operatively coupled to a memory, performs operations according to any aspect or implementation described herein.

### BRIEF DESCRIPTION OF THE DRAWINGS

The present disclosure is illustrated by way of example, and not by way of limitation in the figures of the accompanying drawings.

FIG. 1 is a block diagram illustrating an example system architecture, in accordance with some implementations of the present disclosure.

FIG. 2 is a top schematic view of an example manufacturing system, in accordance with some implementations of the present disclosure.

FIG. 3 is a block diagram illustrating an example predictive architecture, in accordance with some implementations of the present disclosure.

FIG. 4 is a flow chart of a method for training a machine-learning model, according to aspects of the present disclosure.

FIG. 5 is a flow chart of a method for generating a transfer model, according to aspects of the present disclosure.

FIGS. 6A-6C are a set of graphs illustrating a set of traces data, according to aspects of the present disclosure.

FIGS. 7A-7C are a set of graphs illustrating the feature-based vertical scaling technique, according to aspects of the present disclosure.

FIGS. 8A-8C are a set of graphs illustrating the alignment and warping relationship between a source fundamental trace and a target fundamental trace, according to aspects of the present disclosure.

FIG. 9 is a diagram of the framework for applying a transfer model on current trace data related to a target domain to generate predictive data using a machine-learning model trained for a source domain, according to aspects of the present disclosure.

FIG. 10 is a diagram of the framework for applying a transfer model to a machine-learning model trained for a source domain, according to aspects of the present disclosure.

FIG. 11 is a flow chart of a method for applying a transfer model to current trace data related to a target domain, according to aspects of the present disclosure.

FIG. 12 is a flow chart of a method for applying a transfer model to a machine-learning model trained for a source domain, according to aspects of the present disclosure.

FIG. 13 is a block diagram illustrating a computer system, according to certain implementations.

### DETAILED DESCRIPTION

Described herein are technologies directed to methods and mechanisms for trace-based transfer learning at a manufacturing system. In substrate processing (e.g., wafer processing for semiconductor applications), a film can be deposited on a surface of a substrate during a deposition process (e.g., a deposition (CVD) process, an atomic layer deposition (ALD) process, and so forth) performed at a process chamber of a manufacturing system. For example, in a CVD process, the substrate is exposed to one or more precursors, which react on the substrate surface to produce the desired deposit. The film can include one or more layers of materials that are formed during the deposition process, and each layer can include a particular thickness gradient (e.g., changes in the thickness along a layer of the deposited film). For example, a first layer can be formed directly on the surface of the substrate (referred to as a proximal layer or proximal end of the film) and have a first thickness. After the first layer is formed on the surface of the substrate, a second layer having a second thickness can be formed on the first layer. This process continues until the deposition process is completed and a final layer is formed for the film (referred to as the distal layer or distal end of the film). The film can include alternating layers of different materials. For example, the film can include alternating layers of oxide and nitride layers (oxide-nitride-oxide-nitride stack or ONON stack), alternating oxide and polysilicon layers (oxide-polysilicon-oxide-polysilicon stack or OPOP stack), and so forth.

The film can be subjected to, for example, an etch process to form a pattern on the surface of the substrate, a chemical-mechanical polishing/planarization (CMP) process to smooth the surface of the film, or any other process necessary to manufacture the finished substrate. An etch process can include exposing highly energetic process gas (e.g., a plasma) with a sample surface to break down the materials at the surface, which can then be removed by a vacuum system.

A process chamber can perform each substrate manufacturing process (e.g., the deposition process, the etch process, the polishing process, etc.) according to a process recipe. A process recipe defines a particular set of operations to be performed for the substrate during the process and can include one or more settings associated with each operation. For example, a deposition process recipe can include a temperature setting for the process chamber, a pressure setting for the process chamber, a flow rate setting for a precursor for a material included in the film deposited on the substrate surface, etc. Accordingly, the thickness of each film layer can be correlated to these process chamber settings. Execution of a process recipe in a process chamber can be referred to as a process run.

A machine-learning model can be trained to generate analytic and predictive data (e.g., fault detection, predictive maintenance, virtual metrology, etc.). For example, a machine-learning model can be trained using sensor data (e.g., such as trace data) associated with prior manufacturing processes (e.g., deposition processes, etch processes, etc.) and metrology data (e.g., film property data, etch property data, etc.) obtained from the substrates produced by the prior deposition processes. Trace data refers to sensor data received over a period of time (e.g., corresponding to at least part of a recipe or run). Once trained, the machine-learning model can receive, as input, sensor data and generate predictive data. The predictive data can include thickness data or a thickness profile of one or more deposition layers.

A context can refer to any combination of a particular process recipe, a particular process chamber, a day of the week, a particular operator, a location humidity level, or any other process, equipment or set of data related to a manufacturing system. In some systems, a different machine-learning model is trained for each context since a model trained for one context cannot be used to generate analytic and/or predictive data for a different context. Using an individual machine-learning model for each context leads to requiring hundreds or thousands of trained machine-learning models to cover the different contexts of a single manufacturing system for which the analytic and/or predictive data is desirable. This can hamper scalability and reliability. In addition, machine-learning model retraining, tuning, and management can compound maintenance efforts exponentially.

Aspects and implementations of the present disclosure address these and other shortcomings of the existing technology by providing a system configured to implement trace-based transfer learning to allow a machine-learning model to generate predictive data based on run-time data from different contexts. Transfer learning can apply knowledge gained while solving one task to a related task. By reusing and/or transferring information from previously learned tasks to new tasks, learning efficiency can be significantly improved over traditional neural net-based training methods. In some aspects of the present disclosure, a transfer model is generated using trace data obtained from a source domain and from a target domain. A domain can refer to a particular context, such as a process chamber or a process recipe. A source domain can refer to a domain (e.g., process chamber or process recipe) for which a machine-learning model was trained. A target domain can refer to a domain for which a transfer model is to be generated. In some implementations, the source domain and the target domain can be of a certain type, where the type refers to a particular characteristic of the domain (e.g., type of process chamber, type of recipe, type of recipe performed on a process chamber, etc.). For example, in instances where a domain refers to a process chamber (e.g., a source process chamber and a target process chamber), both process chambers can be of the same type in that both process chambers perform a deposition process according to the same recipe, both process chamber perform an etch process, etc. The transfer model can be configured to modify trace data (e.g., sensor data received over a period of time) received during a process run related to the target domain. The modified trace data can be input into the machine-learning model developed for the source domain. The machine-learning model can then generate analytic and/or predictive data for the target domain. Accordingly, the transfer model of the present disclosure enables the source machine-learning model to be reused on data from different contexts so that a new machine-learning model does not need to be trained.

Aspects of the present disclosure result in technological advantages in using a single machine-learning model to generate analytic and/or predictive data for multiple contexts (e.g., different combinations of process chambers running process recipes). In one example, the aspects of the present disclosure can generate a transfer model for each context from which analytic and/or predictive data is desired. Generating the transfer model can required significantly less computation and time resources than training a corresponding machine-learning model. This can result in significant reduction in time and data required to process the obtain desired analytic and/or predictive data for different contexts of a manufacturing system, thus increasing scalability and reliability while decreasing maintenance requirements.

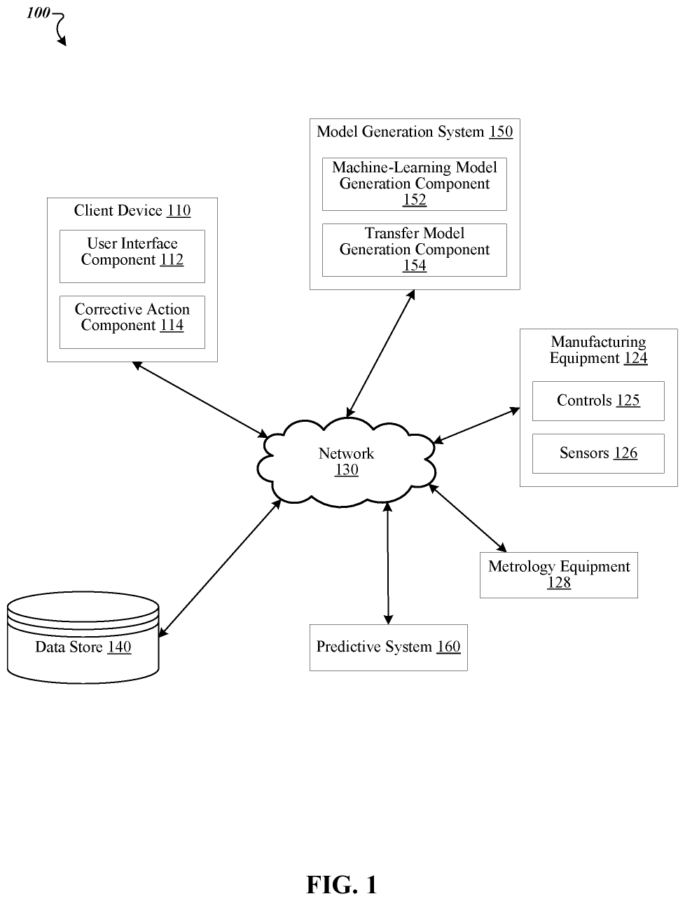

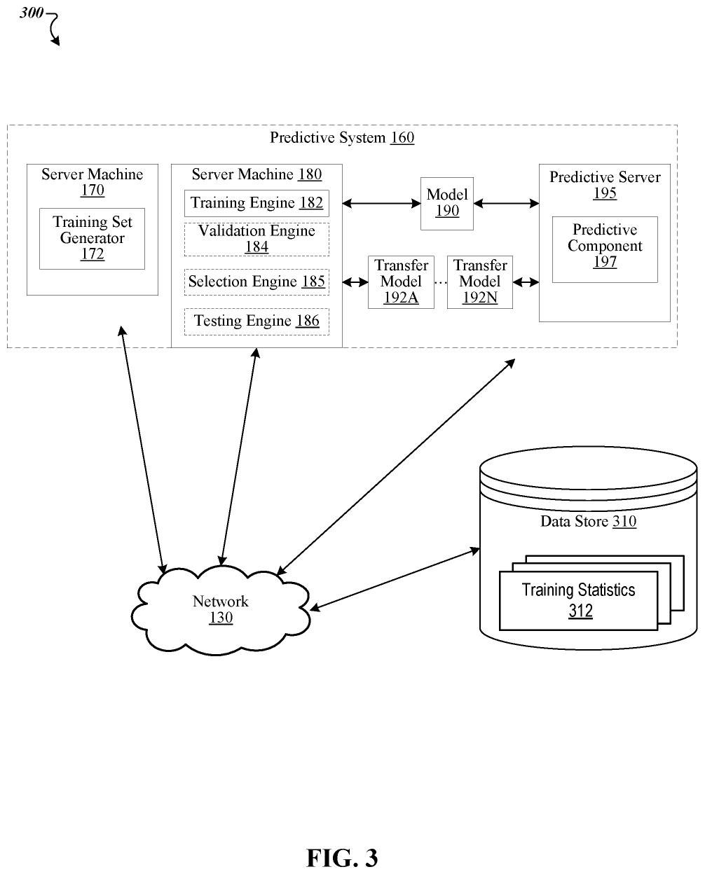

FIG. 1 depicts an illustrative computer system architecture 100, according to aspects of the present disclosure. In some implementations, computer system architecture 100 can be included as part of a manufacturing system for processing substrates. Computer system architecture 100 includes a client device 110, manufacturing equipment 124, predictive system 160 (e.g., to generate predictive data, to provide model adaptation and modification, to use a knowledge base, etc., which will be described in detail in FIG. 3), data store 140, and model generation system 150. The manufacturing equipment 124 can include sensors 126 configured to capture data for a substrate being processed at the manufacturing system. In some implementations, the manufacturing equipment 124 and sensors 126 can be part of a sensor system that includes a sensor server (e.g., field service server (FSS) at a manufacturing facility) and sensor identifier reader (e.g., front opening unified pod (FOUP) radio frequency identification (RFID) reader for sensor system). In some implementations, metrology equipment 128 can be part of computer system architecture 100 that includes a metrology server (e.g., a metrology database, metrology folders, etc.) and metrology identifier reader (e.g., FOUP RFID reader for metrology system).

Manufacturing equipment 124 can produce products, such as electronic devices, following a recipe or performing runs over a period of time. Manufacturing equipment 124 can include a process chamber. Manufacturing equipment 124 can perform a process for a substrate (e.g., a wafer, etc.) at the process chamber. Examples of substrate processes include a deposition process to deposit one or more layers of film on a surface of the substrate, an etch process to form a pattern on the surface of the substrate, etc. Manufacturing equipment 124 can perform each process according to a process recipe. A process recipe defines a particular set of operations to be performed for the substrate during the process and can include one or more settings associated with each operation. For example, a deposition process recipe can include a temperature setting for the process chamber, a pressure setting for the process chamber, a flow rate setting for a precursor for a material included in the film deposited on the substrate surface, etc.

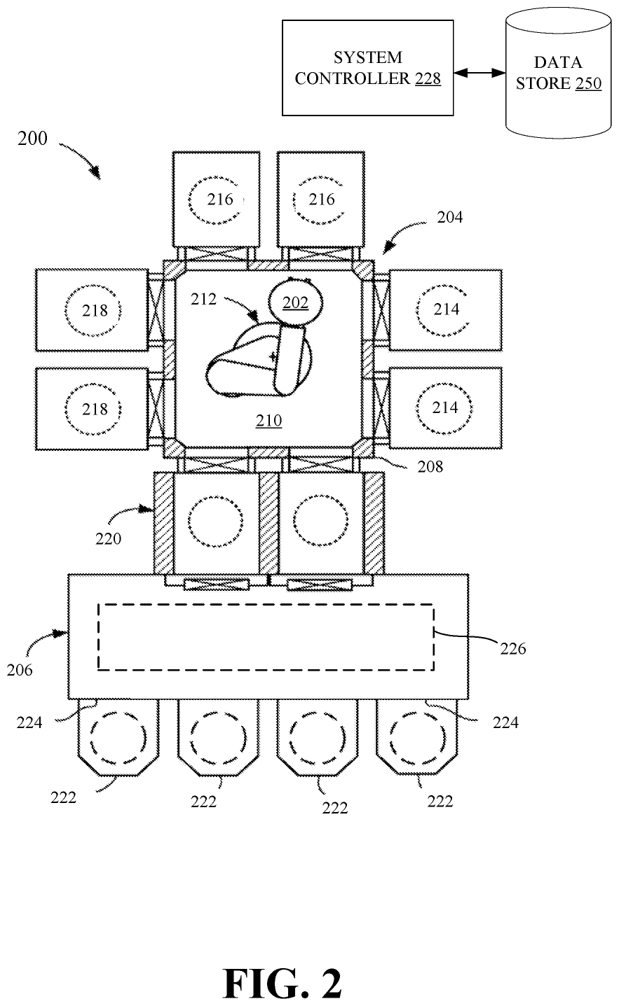

In some implementations, manufacturing equipment 124 includes sensors 126 that are configured to generate data associated with a substrate processed at manufacturing system 100. For example, a process chamber can include one or more sensors configured to generate spectral or non-spectral data associated with the substrate before, during, and/or after a process (e.g., a deposition process, an etch process, etc.) is performed for the substrate. In some implementations, spectral data generated by sensors 126 can indicate a concentration of one or more materials deposited on a surface of a substrate. Sensors 126 configured to generate spectral data associated with a substrate can include reflectometry sensors, ellipsometry sensors, thermal spectra sensors, capacitive sensors, and so forth. Sensors 126 configured to generate non-spectral data associated with a substrate can include temperature sensors, pressure sensors, flow rate sensors, voltage sensors, etc. For example, each sensor 126 can be a temperature sensor, a pressure sensor, a chemical detection sensor, a chemical composition sensor, a gas flow sensor, a motion sensor, a position sensor, an optical sensor, or any and other type of sensors. Some or all of the sensors 126 can include a light source to produce light (or any other electromagnetic radiation), direct it towards a target, such as a component of the machine 100 or a substrate, a film deposited on the substrate, etc., and detect light reflected from the target. The sensors 126 can be located anywhere inside the manufacturing equipment 124 (for example, within any of the chambers including the loading stations, on one or more robots, on a robot blade, between the chambers, and so one), or even outside the manufacturing equipment 124 (where the sensors can test ambient temperature, pressure, gas concentration, and so on). Further details regarding manufacturing equipment 124 are provided with respect to FIG. 2.

In some implementations, sensors 126 provide sensor data (e.g., sensor values, features, trace data) associated with manufacturing equipment 124 (e.g., associated with producing, by manufacturing equipment 124, corresponding products, such as substrates). The manufacturing equipment 124 can produce products following a recipe or by performing runs over a period of time. Sensor data received over a period of time (e.g., corresponding to at least part of a recipe or run) can be referred to as trace data (e.g., historical trace data, current trace data, etc.) received from different sensors 126 over time. Sensor data can include a value of one or more of temperature (e.g., heater temperature), spacing (SP), pressure, high frequency radio frequency (HFRF), voltage of electrostatic chuck (ESC), electrical current, material flow, power, voltage, etc. Sensor data can be associated with or indicative of manufacturing parameters such as hardware parameters, such as settings or components (e.g., size, type, etc.) of the manufacturing equipment 124, or process parameters of the manufacturing equipment 124. The sensor data can be provided while the manufacturing equipment 124 is performing manufacturing processes (e.g., equipment readings when processing products). The sensor data can be different for each substrate.

In some implementations, manufacturing equipment 124 can include controls 125. Controls 125 can include one or more components or sub-systems configured to enable and/or control one or more processes of manufacturing equipment 124. For example, a sub-system can include a pressure sub-system, a flow sub-system, a temperature sub-system and so forth, each sub-system having one or more components. The component can include, for example, a pressure pump, a vacuum, a gas deliver line, a plasma etcher, actuators etc. In some implementations, controls 125 can be managed based on data from sensors 126, input from client device 110, etc.

Metrology equipment 128 can provide metrology data associated with substrates processed by manufacturing equipment 124. The metrology data can include a value of film property data (e.g., wafer spatial film properties), dimensions (e.g., thickness, height, etc.), dielectric constant, dopant concentration, density, defects, etc. In some implementations, the metrology data can further include a value of one or more surface profile property data (e.g., an etch rate, an etch rate uniformity, a critical dimension of one or more features included on a surface of the substrate, a critical dimension uniformity across the surface of the substrate, an edge placement error, etc.). The metrology data can be of a finished or semi-finished product. The metrology data can be different for each substrate. Metrology data can be generated using, for example, reflectometry techniques, ellipsometry techniques, TEM techniques, and so forth.

In some implementations, metrology equipment 128 can be included as part of the manufacturing equipment 124. For example, metrology equipment 128 can be included inside of or coupled to a process chamber and configured to generate metrology data for a substrate before, during, and/or after a process (e.g., a deposition process, an etch process, etc.) while the substrate remains in the process chamber. In some instances, metrology equipment 128 can be referred to as in-situ metrology equipment. In another example, metrology equipment 128 can be coupled to another station of manufacturing equipment 124. For example, metrology equipment can be coupled to a transfer chamber, such as transfer chamber 210 of FIG. 2, a load lock, such as load lock 220, or a factory interface, such as factory interface 206.

The client device 110 can include a computing device such as personal computers (PCs), laptops, mobile phones, smart phones, tablet computers, netbook computers, network connected televisions (“smart TVs”), network-connected media players (e.g., Blu-ray player), a set-top box, over-the-top (OTT) streaming devices, operator boxes, etc. In some implementations, the metrology data can be received from the client device 110. Client device 110 can display a graphical user interface (GUI), where the GUI enables the user to provide, as input, metrology measurement values for substrates processed at the manufacturing system. The client device 110 can include user interface (UI) component 112 and corrective action component 114. UI component 112 can receive user input (e.g., via a Graphical User Interface (GUI) displayed via the client device 110) associate with generating a machine-learning model, generating a transfer model, updating one or more machine-learning models, etc. The machine-learning model and transfer model can be generated by the predictive system 160, which is discussed with regards to FIG. 3. Each client device 110 can include an operating system that allows users to one or more of generate, view, or edit data (e.g., indication associated with manufacturing equipment 124, corrective actions associated with manufacturing equipment 124, etc.).

Corrective action component 114 can receive user input (e.g., via a Graphical User Interface (GUI) displayed via the client device 110) of an indication associated with manufacturing equipment 124. In some implementations, the corrective action component 114 transmits the indication to the predictive system 160, receives output (e.g., predictive data) from the predictive system 160, determines a corrective action based on the output, and causes the corrective action to be implemented. For example, responsive to receiving an indication that sensor data satisfied a threshold criterion (e.g., exceeded or fell below a fault detection limit), the correction action component 114 can perform one or more corrective action (e.g., increase power, decrease flowrate, etc.). The corrective actions can be stored in a fault pattern library on data store 140.

Data store 140 can be a memory (e.g., random access memory), a drive (e.g., a hard drive, a flash drive), a database system, or another type of component or device capable of storing data. Data store 140 can include multiple storage components (e.g., multiple drives or multiple databases) that can span multiple computing devices (e.g., multiple server computers). The data store 140 can store data associated with processing a substrate at manufacturing equipment 124. For example, data store 140 can store data collected by sensors 126 at manufacturing equipment 124 before, during, or after a substrate process (referred to as process data). Process data can refer to historical process data (e.g., process data generated for a prior substrate processed at the manufacturing system) and/or current process data (e.g., process data generated for a current substrate processed at the manufacturing system). Data store can also store spectral data or non-spectral data associated with a portion of a substrate processed at manufacturing equipment 124. Spectral data can include historical spectral data and/or current spectral data.

Data store 140 can also store contextual data associated with one or more substrates processed at the manufacturing system. Contextual data can include a recipe name, recipe step number, preventive maintenance indicator, operator, etc. Contextual data can refer to historical contextual data (e.g., contextual data associated with a prior process performed for a prior substrate) and/or current process data (e.g., contextual data associated with current process or a future process to be performed for a prior substrate). The contextual data can further include identify sensors that are associated with a particular sub-system of a process chamber.

Data store 140 can also store task data. Task data can include one or more sets of operations to be performed for the substrate during a deposition process and can include one or more settings associated with each operation. For example, task data for a deposition process can include a temperature setting for a process chamber, a pressure setting for a process chamber, a flow rate setting for a precursor for a material of a film deposited on a substrate, etc. In another example, task data can include controlling pressure at a defined pressure point for the flow value. Task data can refer to historical task data (e.g., task data associated with a prior process performed for a prior substrate) and/or current task data (e.g., task data associated with current process or a future process to be performed for a substrate).

In some implementations, data store 140 can be configured to store data that is not accessible to a user of the manufacturing system. For example, process data, spectral data, contextual data, etc. obtained for a substrate being processed at the manufacturing system is not accessible to a user (e.g., an operator) of the manufacturing system. In some implementations, all data stored at data store 140 can be inaccessible by the user of the manufacturing system. In other or similar implementations, a portion of data stored at data store 140 can be inaccessible by the user while another portion of data stored at data store 140 can be accessible by the user. In some implementations, one or more portions of data stored at data store 140 can be encrypted using an encryption mechanism that is unknown to the user (e.g., data is encrypted using a private encryption key). In other or similar implementations, data store 140 can include multiple data stores where data that is inaccessible to the user is stored in one or more first data stores and data that is accessible to the user is stored in one or more second data stores.

In some implementations, data store 140 can be configured to store data associated with known fault patterns. A fault pattern can be a one or more values (e.g., a vector, a scalar, etc.) associated with one or more issues or failures associated with a process chamber sub-system. In some implementations, a fault pattern can be associated with a corrective action. For example, a fault pattern can include parameter adjustment steps to correct the issue or failure indicated by the fault pattern. For example, the predictive system or the corrective action module can compare a determined fault pattern (determined from data obtained from of one or more sensors of a sensor cluster) to a library of known fault patterns to determine the type of failure experienced by a sub-system, the cause of the failure, the recommended corrective action to correct the fault, and so forth.

In some implementations, model generation system 150 can be configured to generate a machine-learning model(s) 190, and to generate one or more transfer model 192A-N. Model generation system 150 can include one or more computing devices such as a rackmount server, a router computer, a server computer, a personal computer, a mainframe computer, a laptop computer, a tablet computer, a desktop computer, a GPU, an ASIC, etc. Model generation system 150 can include a data storage device (e.g., one or more disk drives and/or solid-state drives), a main memory, a static memory, a network interface, and/or other components. Model generation system 150 can execute instructions to perform any one or more of the methodologies and/or implementations described herein. In some implementations, model generation system 150 can identify and/or obtain one or more features of a machine-learning model (e.g., model 190) to generate a transfer model (e.g., model 192A-N). In some implementations, model generation system 150 can execute instructions to control one or more operations at predictive system 160 in accordance with a received input (e.g., a user input, a corrective action command, etc.). In some implementations, model generation system 150 can execute instructions to control one or more operations at manufacturing equipment 124 in accordance with a received input (e.g., a user input, a corrective action command, etc.). The instructions can be stored on a computer readable storage medium, which can include the main memory, static memory, secondary storage and/or processing device (during execution of the instructions).

Machine generation system 150 can include machine-learning generation component 152 and transfer model generation component 154. Machine-learning model generation component 152 can be configured to instruct predictive system 160 to generate a machine-learning model 190. Transfer model generation component 154 can be configured to instruct predictive system 160 to generate one or more transfer models 192A-N. A transfer model 192A-N can be configured to modify trace data (or other sensor data) received during a process run related to the target domain. The modified trace data can be input into the machine-learning model 190 developed for a different domain (a source domain). The machine-learning model 190 can then generate analytic and/or predictive data for the target domain. The transfer model 192A-N enables the machine-learning model 190 to be reused on data from different contexts without the need to train a new machine-learning model for said context.

The client device 110, manufacturing equipment 124, sensors 126, predictive system 160, and data store 140 can be coupled to each other via a network 130. In some implementations, network 130 is a public network that provides client device 110 with access to predictive system 160, data store 140, manufacturing equipment 124 (not shown) and other publicly available computing devices. In some implementations, network 130 is a private network that provides client device 110 access to manufacturing equipment 124, data store 140, predictive system 160, and other privately available computing devices. Network 130 can include one or more wide area networks (WANs), local area networks (LANs), wired networks (e.g., Ethernet network), wireless networks (e.g., an 802.11 network or a Wi-Fi network), cellular networks (e.g., a Long-Term Evolution (LTE) network), routers, hubs, switches, server computers, cloud computing networks, and/or a combination thereof.

In implementations, a “user” can be represented as a single individual. However, other implementations of the disclosure encompass a “user” being an entity controlled by a plurality of users and/or an automated source. For example, a set of individual users federated as a group of administrators can be considered a “user.”

FIG. 2 is a top schematic view of an example manufacturing system 200, according to aspects of the present disclosure. Manufacturing system 200 can perform one or more processes on a substrate 202. Substrate 202 can be any suitably rigid, fixed-dimension, planar article, such as, e.g., a silicon-containing disc or wafer, a patterned wafer, a glass plate, or the like, suitable for fabricating electronic devices or circuit components thereon.

Manufacturing system 200 can include a process tool 204 and a factory interface 206 coupled to process tool 204. Process tool 204 can include a housing 208 having a transfer chamber 210 therein. Transfer chamber 210 can include one or more process chambers (also referred to as processing chambers) 214, 216, 218 disposed therearound and coupled thereto. Process chambers 214, 216, 218 can be coupled to transfer chamber 210 through respective ports, such as slit valves or the like. Transfer chamber 210 can also include a transfer chamber robot 212 configured to transfer substrate 202 between process chambers 214, 216, 218, load lock 220, etc. Transfer chamber robot 212 can include one or multiple arms where each arm includes one or more end effectors at the end of each arm. The end effector can be configured to handle particular objects, such as wafers, sensor discs, sensor tools, etc.

Process chambers 214, 216, 218 can be adapted to carry out any number of processes on substrates 202. A same or different substrate process can take place in each processing chamber 214, 216, 218. A substrate process can include atomic layer deposition (ALD), physical vapor deposition (PVD), chemical vapor deposition (CVD), etching, annealing, curing, pre-cleaning, metal or metal oxide removal, or the like. Other processes can be carried out on substrates therein. Process chambers 214, 216, 218 can each include one or more sensors configured to capture data for substrate 202 before, after, or during a substrate process. For example, the one or more sensors can be configured to capture spectral data and/or non-spectral data for a portion of substrate 202 during a substrate process. In other or similar implementations, the one or more sensors can be configured to capture data associated with the environment within process chamber 214, 216, 218 before, after, or during the substrate process. For example, the one or more sensors can be configured to capture data associated with a temperature, a pressure, a gas concentration, etc. of the environment within process chamber 214, 216, 218 during the substrate process.

In some implementations, metrology equipment (not shown) can be located within the process tool. In other implementations, metrology equipment (not shown) can be located within one or more process chambers 214, 216, 218. In some implementations, the substrate can be placed onto metrology equipment using transfer chamber robot 212. In other implementations, the metrology equipment can be part of the substrate support assembly (not shown). Metrology equipment can provide metrology data associated with substrates processed by manufacturing equipment 124. The metrology data can include a value of film property data (e.g., wafer spatial film properties), dimensions (e.g., thickness, height, etc.), dielectric constant, dopant concentration, density, defects, etc. In some implementations, the metrology data can further include a value of one or more surface profile property data (e.g., an etch rate, an etch rate uniformity, a critical dimension of one or more features included on a surface of the substrate, a critical dimension uniformity across the surface of the substrate, an edge placement error, etc.). The metrology data can be of a finished or semi-finished product. The metrology data can be different for each substrate. Metrology data can be generated using, for example, reflectometry techniques, ellipsometry techniques, TEM techniques, and so forth.

A load lock 220 can also be coupled to housing 208 and transfer chamber 210. Load lock 220 can be configured to interface with, and be coupled to, transfer chamber 210 on one side and factory interface 206. Load lock 220 can have an environmentally-controlled atmosphere that can be changed from a vacuum environment (wherein substrates can be transferred to and from transfer chamber 210) to an at or near atmospheric-pressure inert-gas environment (wherein substrates can be transferred to and from factory interface 206) in some implementations. Factory interface 206 can be any suitable enclosure, such as, e.g., an Equipment Front End Module (EFEM). Factory interface 206 can be configured to receive substrates 202 from substrate carriers 222 (e.g., Front Opening Unified Pods (FOUPs)) docked at various load ports 224 of factory interface 206. A factory interface robot 226 (shown dotted) can be configured to transfer substrates 202 between carriers (also referred to as containers) 222 and load lock 220. Carriers 222 can be a substrate storage carrier or a replacement part storage carrier.

Manufacturing system 200 can also be connected to a client device (e.g., client device 110, not shown) that is configured to provide information regarding manufacturing system 200 to a user (e.g., an operator). In some implementations, the client device can provide information to a user of manufacturing system 200 via one or more graphical user interfaces (GUIs). For example, the client device can provide information regarding a target thickness profile for a film to be deposited on a surface of a substrate 202 during a deposition process performed at a process chamber 214, 216, 218 via a GUI. The client device can also provide information regarding anomaly detection and fault classification, in accordance with implementations described herein.

Manufacturing system 200 can also include a system controller 228. System controller 228 can be and/or include a computing device such as a personal computer, a server computer, a programmable logic controller (PLC), a microcontroller, and so on. System controller 228 can include one or more processing devices, which can be general-purpose processing devices such as a microprocessor, central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device can also be one or more special-purpose processing devices such as an application specific integrated circuit (ASIC), a field programmable gate array (FPGA), a digital signal processor (DSP), network processor, or the like. System controller 228 can include a data storage device (e.g., one or more disk drives and/or solid-state drives), a main memory, a static memory, a network interface, and/or other components. System controller 228 can execute instructions to perform any one or more of the methodologies and/or implementations described herein. In some implementations, system controller 228 can execute instructions to perform one or more operations at manufacturing system 200 in accordance with a process recipe. The instructions can be stored on a computer readable storage medium, which can include the main memory, static memory, secondary storage and/or processing device (during execution of the instructions).

System controller 228 can receive data from sensors (e.g., sensors 126, now shown) included on or within various portions of manufacturing system 200 (e.g., processing chambers 214, 216, 218, transfer chamber 210, load lock 220, etc.). In some implementations, data received by the system controller 228 can include spectral data and/or non-spectral data for a portion of substrate 202. In other or similar implementations, data received by the system controller 228 can include data associated with processing substrate 202 at processing chamber 214, 216, 218, as described previously. For purposes of the present description, system controller 228 is described as receiving data from sensors included within process chambers 214, 216, 218. However, system controller 228 can receive data from any portion of manufacturing system 200 and can use data received from the portion in accordance with implementations described herein. In an illustrative example, system controller 228 can receive data from one or more sensors for process chamber 214, 216, 218 before, after, or during a substrate process at the process chamber 214, 216, 218. Data received from sensors of the various portions of manufacturing system 200 can be stored in a data store 250. Data store 250 can be included as a component within system controller 228 or can be a separate component from system controller 228. In some implementations, data store 250 can be data store 140 described with respect to FIG. 1.

FIG. 3 depicts an illustrative predictive architecture 300, according to aspects of the present disclosure. In some implementations, predictive architecture 300 include predictive system 160, network 130, and data store 310 (which can be similar to the same as data store 140). In some implementations, predictive system 160 can use data obtained from a trained machine-learning model (e.g., model 190) to generate predictive data (e.g., predictive metrology data) for a process chamber 214, 216, 218. For example, model 190 can use sensor data as input, and generate, as output, predictive metrology data for a particular process chamber. In some implementations, predictive system 160 can generate one or more transfer models 192A-192N using training data, such as trace data, used to train machine-learning model 190, and trace data related to a target domain for which the transfer model is generated. Predictive system 160 can then use transfer models 192A-N and machine-learning model 190 to generate analytic and/or predictive data (e.g., predictive metrology data, fault detection data, predictive maintenance data, etc.) based on sensor data (e.g., trace data) obtained from the target domain.

In some implementations, predictive system 160 can include predictive server 112, server machines 170 and 180, and predictive server 195. The predictive server 160, server machine 170, server machine 180, and predictive server 195 can each include one or more computing devices such as a rackmount server, a router computer, a server computer, a personal computer, a mainframe computer, a laptop computer, a tablet computer, a desktop computer, Graphics Processing Unit (GPU), accelerator Application-Specific Integrated Circuit (ASIC) (e.g., Tensor Processing Unit (TPU)), etc.

Server machine 170 includes a training set generator 172 that is capable of generating training data sets (e.g., a set of data inputs and a set of target outputs) to train, validate, and/or test a machine-learning model 190 and/or transfer model 192A-N. Machine-learning model 190 and/or transfer model 192A-N can be any algorithmic model capable of learning from data. In some implementations, machine-learning model 190 and/or transfer model 192A-N can be a predictive model. In some implementations, transfer model 192A-N can be an algorithmic, formulaic, or statistics-based model. In some implementations, the data set generator 172 can partition the training data into a training set, a validating set, and a testing set, which can be stored, as part of the training statistics 312, in the training data store 310. Training statistics 312 which can be accessible to the computing device predictive system 160 directly or via network 130. In some implementations, the predictive system 160 generates multiple sets of training data.

Server machine 180 can include a training engine 182, a validation engine 184, a selection engine 185, and/or a testing engine 186. An engine can refer to hardware (e.g., circuitry, dedicated logic, programmable logic, microcode, processing device, etc.), software (such as instructions run on a processing device, a general-purpose computer system, or a dedicated machine), firmware, microcode, or a combination thereof. Training engine 182 can be capable of training one or more machine-learning model 190, 192A-N. Machine-learning model 190 and/or transfer model 192A-N refer to the model artifact that is created by the training engine 182 using the training data (also referred to herein as a training set) that includes training inputs and corresponding target outputs (correct answers for respective training inputs). The training engine 182 can find patterns in the training data that map the training input to the target output (the answer to be predicted), and provide the machine-learning model 190 and/or transfer model 192A-N that captures these patterns. The machine-learning model 190 and/or transfer model 192A-N can use one or more of a statistical modelling, support vector machine (SVM), Radial Basis Function (RBF), clustering, supervised machine-learning, semi-supervised machine-learning, unsupervised machine-learning, k-nearest neighbor algorithm (k-NN), linear regression, random forest, neural network (e.g., artificial neural network), etc.

One type of machine learning model that can be used to perform some or all of the above tasks is an artificial neural network, such as a deep neural network. Artificial neural networks generally include a feature representation component with a classifier or regression layers that map features to a desired output space. A convolutional neural network (CNN), for example, hosts multiple layers of convolutional filters. Pooling is performed, and non-linearities can be addressed, at lower layers, on top of which a multi-layer perceptron is commonly appended, mapping top layer features extracted by the convolutional layers to decisions (e.g., classification outputs). Deep learning is a class of machine learning algorithms that use a cascade of multiple layers of nonlinear processing units for feature extraction and transformation. Each successive layer uses the output from the previous layer as input. Deep neural networks can learn in a supervised (e.g., classification) and/or unsupervised (e.g., pattern analysis) manner. Deep neural networks include a hierarchy of layers, where the different layers learn different levels of representations that correspond to different levels of abstraction. In deep learning, each level learns to transform its input data into a slightly more abstract and composite representation. In a plasma process tuning, for example, the raw input can be process result profiles (e.g., thickness profiles indicative of one or more thickness values across a surface of a substrate); the second layer can compose feature data associated with a status of one or more zones of controlled elements of a plasma process system (e.g., orientation of zones, plasma exposure duration, etc.); the third layer can include a starting recipe (e.g., a recipe used as a starting point for determining an updated process recipe the process a substrate to generate a process result the meets threshold criteria). Notably, a deep learning process can learn which features to optimally place in which level on its own. The “deep” in “deep learning” refers to the number of layers through which the data is transformed. More precisely, deep learning systems have a substantial credit assignment path (CAP) depth. The CAP is the chain of transformations from input to output. CAPs describe potentially causal connections between input and output. For a feedforward neural network, the depth of the CAPs can be that of the network and can be the number of hidden layers plus one. For recurrent neural networks, in which a signal can propagate through a layer more than once, the CAP depth is potentially unlimited.

In one implementation, one or more machine learning model is a recurrent neural network (RNN). An RNN is a type of neural network that includes a memory to enable the neural network to capture temporal dependencies. An RNN is able to learn input-output mappings that depend on both a current input and past inputs. The RNN will address past and future flow rate measurements and make predictions based on this continuous metrology information. RNNs can be trained using a training dataset to generate a fixed number of outputs (e.g., to determine a set of substrate processing rates, determine modification to a substrate process recipe). One type of RNN that can be used is a long short term memory (LSTM) neural network.

Training of a neural network can be achieved in a supervised learning manner, which involves feeding a training dataset consisting of labeled inputs through the network, observing its outputs, defining an error (by measuring the difference between the outputs and the label values), and using techniques such as deep gradient descent and backpropagation to tune the weights of the network across all its layers and nodes such that the error is minimized. In many applications, repeating this process across the many labeled inputs in the training dataset yields a network that can produce correct output when presented with inputs that are different than the ones present in the training dataset.

A training dataset containing hundreds, thousands, tens of thousands, hundreds of thousands or more sensor data and/or process result data (e.g., metrology data such as one or more thickness profiles associated with the sensor data) can be used to form a training dataset.

To effectuate training, processing logic can input the training dataset(s) into one or more untrained machine learning models. Prior to inputting a first input into a machine learning model, the machine learning model can be initialized. Processing logic trains the untrained machine learning model(s) based on the training dataset(s) to generate one or more trained machine learning models that perform various operations as set forth above. Training can be performed by inputting one or more of the sensor data into the machine learning model one at a time.

The machine learning model processes the input to generate an output. An artificial neural network includes an input layer that consists of values in a data point. The next layer is called a hidden layer, and nodes at the hidden layer each receive one or more of the input values. Each node contains parameters (e.g., weights) to apply to the input values. Each node therefore essentially inputs the input values into a multivariate function (e.g., a non-linear mathematical transformation) to produce an output value. A next layer can be another hidden layer or an output layer. In either case, the nodes at the next layer receive the output values from the nodes at the previous layer, and each node applies weights to those values and then generates its own output value. This can be performed at each layer. A final layer is the output layer, where there is one node for each class, prediction and/or output that the machine learning model can produce.

Accordingly, the output can include one or more predictions or inferences. In some implementations, an output prediction or inference can include one or more predictions of sensor group classifications, sensor rankings, etc. In some implementations, an output prediction or inference can include one or more predictions of anomaly data, fault data, fault detection limits, etc. Processing logic determines an error (i.e., a classification error) based on the differences between the output (e.g., predictions or inferences) of the machine learning model and target labels associated with the input training data. Processing logic adjusts weights of one or more nodes in the machine learning model based on the error. An error term or delta can be determined for each node in the artificial neural network. Based on this error, the artificial neural network adjusts one or more of its parameters for one or more of its nodes (the weights for one or more inputs of a node). Parameters can be updated in a back propagation manner, such that nodes at a highest layer are updated first, followed by nodes at a next layer, and so on. An artificial neural network contains multiple layers of “neurons”, where each layer receives as input values from neurons at a previous layer. The parameters for each neuron include weights associated with the values that are received from each of the neurons at a previous layer. Accordingly, adjusting the parameters can include adjusting the weights assigned to each of the inputs for one or more neurons at one or more layers in the artificial neural network.

After one or more rounds of training, processing logic can determine whether a stopping criterion has been met. A stopping criterion can be a target level of accuracy, a target number of processed images from the training dataset, a target amount of change to parameters over one or more previous data points, a combination thereof and/or other criteria. In one implementation, the stopping criteria is met when at least a minimum number of data points have been processed and at least a threshold accuracy is achieved. The threshold accuracy can be, for example, 70%, 80% or 90% accuracy. In one implementation, the stopping criterion is met if accuracy of the machine learning model has stopped improving. If the stopping criterion has not been met, further training is performed. If the stopping criterion has been met, training can be complete. Once the machine learning model is trained, a reserved portion of the training dataset can be used to test the model.

Once one or more trained machine learning model 190 and/or transfer model 192A-N are generated, they can be stored in predictive server 195 as predictive component 197 or as a component of predictive component 197.

The validation engine 184 can be capable of validating model 190 and/or transfer model 192A-N using a corresponding set of features of a validation set from training set generator 172. Once the model parameters have been optimized, model validation can be performed to determine whether the model has improved and to determine a current accuracy of the deep learning model. The validation engine 184 can determine an accuracy of machine-learning model 190 and/or transfer model 192A-N based on the corresponding sets of features of the validation set. The validation engine 184 can discard a trained machine-learning model 190 and/or transfer model 192A-N that has an accuracy that does not meet a threshold accuracy. In some implementations, the selection engine 185 can be capable of selecting a trained machine-learning model 190 and/or transfer model 192A-N that has an accuracy that meets a threshold accuracy. In some implementations, the selection engine 185 can be capable of selecting the trained machine-learning model 190 and/or transfer model 192A-N that has the highest accuracy of the trained machine-learning model 190 and/or transfer model 192A-N.

The testing engine 186 can be capable of testing a trained machine-learning model 190 using a corresponding set of features of a testing set from data set generator 172. For example, a first trained machine-learning model 190 and/or transfer model 192A-N that was trained using a first set of features of the training set can be tested using the first set of features of the testing set. The testing engine 186 can determine a trained machine-learning model 190 and/or transfer model 192A-N that has the highest accuracy of all of the trained machine-learning models based on the testing sets.

As described in detail below, predictive server 195 includes a predictive component 197 that is capable of providing trace data to trained machine-learning model 190 and/or transfer model 192A-N to obtain one or more outputs. The predictive server 195 can further provide predictive or analytic data (e.g., predictive maintenance data, virtual metrology data, fault detection data, etc.). This will be explained in further detail below.

It should be noted that in some other implementations, the functions of server machines 170 and 180, as well as predictive server 195, can be provided by a fewer number of machines. For example, in some implementations, server machines 170 and 180 can be integrated into a single machine, while in some other or similar implementations, server machines 170 and 180, as well as predictive server 195, can be integrated into a single machine.

In general, functions described in one implementation as being performed by server machine 170, server machine 180, and/or predictive server 195 can also be performed on client device 110. In addition, the functionality attributed to a particular component can be performed by different or multiple components operating together.

In some implementations, a manufacturing system can include more than one process chambers. For example, example manufacturing system 200 of FIG. 2 illustrates multiple process chambers 214, 216, 218. It should be noted that, in some implementations, data obtained to train the machine-learning model 190 and data collected to be provided as input to the machine-learning model can be associated with the same process chamber of the manufacturing system. In other or similar implementations, data obtained to train the machine-learning model 190 and/or transfer model 192A-N and data collected to be provided as input to the machine-learning model 190 and/or transfer model 192A-N can be associated with different process chambers of the manufacturing system. In other or similar implementations, data obtained to train the machine-learning model 190 and/or transfer model 192A-N can be associated with a process chamber of a first manufacturing system and data collected to be provide as input to the machine-learning model 190 and/or transfer model 192A-N can be associated with a process chamber of a second manufacturing system.

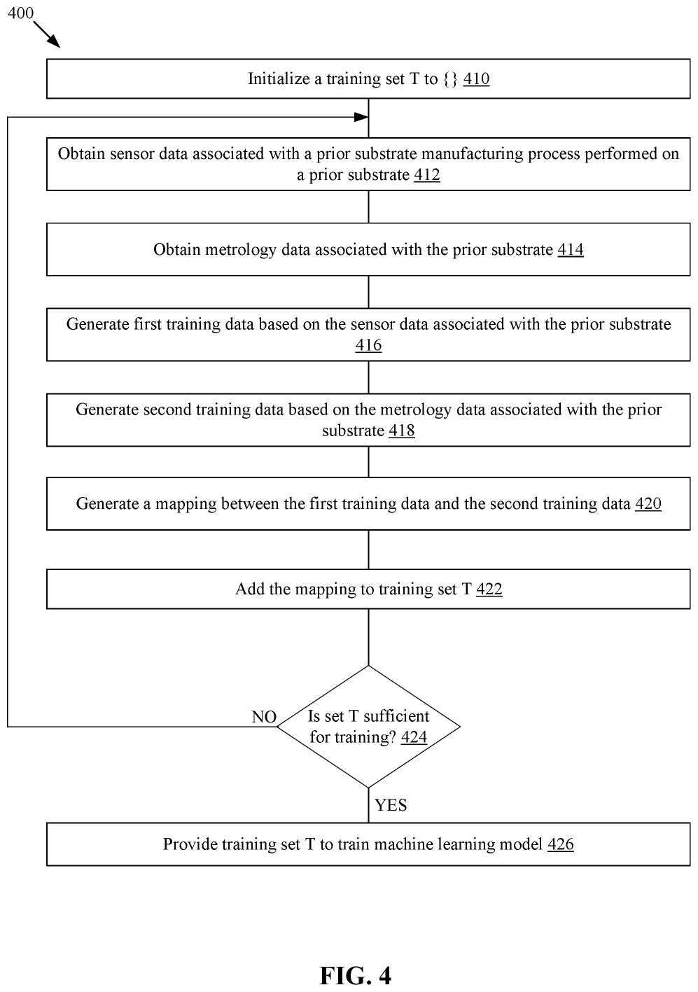

FIG. 4 is a flow chart of a method 400 for training a machine-learning model, according to aspects of the present disclosure. Method 400 is performed by processing logic that can include hardware (circuitry, dedicated logic, etc.), software (such as is run on a general-purpose computer system or a dedicated machine), firmware, or some combination thereof. In one implementation, method 400 can be performed by a computer system, such as computer system architecture 100 of FIG. 1. In other or similar implementations, one or more operations of method 400 can be performed by one or more other machines not depicted in the figures. In some aspects, one or more operations of method 400 can be performed by client device 110, model generation system 150, server machine 170, server machine 180, and/or predictive server 195.

For simplicity of explanation, the methods are depicted and described as a series of acts. However, acts in accordance with this disclosure can occur in various orders and/or concurrently, and with other acts not presented and described herein. Furthermore, not all illustrated acts can be performed to implement the methods in accordance with the disclosed subject matter. In addition, those skilled in the art will understand and appreciate that the methods could alternatively be represented as a series of interrelated states via a state diagram or events. Additionally, it should be appreciated that the methods disclosed in this specification are capable of being stored on an article of manufacture to facilitate transporting and transferring such methods to computing devices. The term article of manufacture, as used herein, is intended to encompass a computer program accessible from any computer-readable device or storage media.

Method 400 relates to training a machine-learning model to generate one or more values (predictive data) associated with the expected metrology data generated, by the process chamber executing a particular process recipe, on a virtual substrate. In other implementations, a machine-learning model can be trained to generate predictive maintenance data, fault detection data, and so forth.

At operation 410, processing logic initializes a training set T to an empty set (e.g., { }).

At operation 412, processing logic obtains sensor data associated with a prior substrate manufacturing process (e.g., deposition process, etch process, etc.) to perform one or more processes on a prior substrate. In some implementations, the sensor data associated with the substrate manufacturing process is historical data associated with one or more prior deposition settings for a prior deposition process previously performed for a prior substrate at a manufacturing system. In some implementations, the sensor can be associated with a prior etching process performed on the prior substrate, or any other process performed in the process chamber.

At operation 414, processing logic obtains metrology data associated with the prior substrate. For example, the metrology data can include film thickness data associated with a film deposited on the surface of the prior substrate, etch data associated with an etch process performed on the substrate, etc. Film thickness data can refer to a thickness measurement of individual film layer(s), total film stack(s), and/or aggregated layer stack(s). Film thickness data can include historical film thickness data for a prior film deposited on a surface of a prior substrate. In some implementations, the historical film thickness data for the prior film can correspond to a historical metrology measurement value associated with the prior film. Processing logic can obtain the metrology data (e.g., film thickness data associated with the deposited film, etch data associated with an etch process performed on the substrate, etc.) from data store 140, in accordance with previously described implementations.

At operation 416, processing logic generates first training data based on the obtained sensor data associated with the prior substrate manufacturing process performed on the prior substrate. At operation 418, processing logic generates second training data based on the metrology data (e.g., film thickness, etch depth, etc.) obtained from the prior substrate.

At operation 420, processing logic generates a mapping between the first training data and the second training data. The mapping refers to the first training data that includes or is based on sensor data for the prior substrate manufacturing process performed for the prior substrate and the second training data that includes or is based on metrology data obtained from the prior substrate, where the first training data is associated with (or mapped to) the second training data. At operation 422, processing logic adds the mapping to the training set T.

At operation 424, processing logic determines whether the training set, T, includes a sufficient amount of training data to train a machine-learning model. It should be noted that in some implementations, the sufficiency of training set T can be determined based simply on the number of mappings in the training set, while in some other implementations, the sufficiency of training set T can be determined based on one or more other criteria (e.g., a measure of diversity of the training examples, etc.) in addition to, or instead of, the number of input/output mappings. Responsive to determining the training set does not include a sufficient amount of training data to train the machine-learning model, method 400 returns to operation 412. Responsive to determining the training set T includes a sufficient amount of training data to train the machine-learning model, method 400 continues to operation 426.

At operation 426, processing logic provides the training set T to train the machine-learning model. In one implementation, the training set T is provided to training engine 182 of server machine 180 to perform the training. In the case of a neural network, for example, input values of a given input/output mapping are input to the neural network, and output values of the input/output mapping are stored in the output nodes of the neural network. The connection weights in the neural network are then adjusted in accordance with a learning algorithm (e.g., backpropagation, etc.), and the procedure is repeated for the other input/output mappings in the training set T.

In some implementations, the processing logic can perform outlier detection methods to remove anomalies from the training set T prior to training the machine-learning model. Outlier detection methods can include techniques that identify values that differs significantly from the majority the training data. These values can be generated from errors, noise, etc.

After operation 426, machine-learning model can be used to generate one or more values (predictive data) associated with the expected metrology data generated, by the process chamber executing a particular process recipe, on a virtual substrate. Method 400 is an illustrative example of generating one type of machine-learning model. It is noted that other methods for generating the other types of machine-learning models can be used.

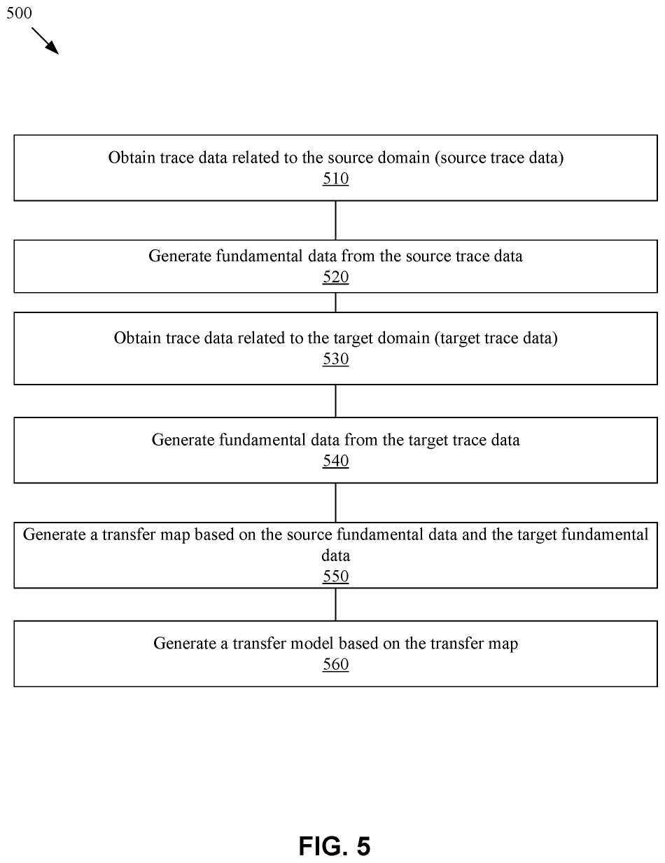

FIG. 5 is a flow chart of a method 500 for generating a transfer model, according to aspects of the present disclosure. Method 500 is performed by processing logic that can include hardware (circuitry, dedicated logic, etc.), software (such as is run on a general-purpose computer system or a dedicated machine), firmware, or some combination thereof. In one implementation, method 500 can be performed by a computer system, such as computer system architecture 100 of FIG. 1. In other or similar implementations, one or more operations of method 500 can be performed by one or more other machines not depicted in the figures. In some aspects, one or more operations of method 500 can be performed by client device 110, model generation system 150, server machine 170, server machine 180, and/or predictive server 195.

Method 500 will be discussed in reference to a source domain and a target domain. The source domain can refer to a process chamber or a process recipe for which a machine-learning model was generated using, for example, method 400 of FIG. 4. The target domain can refer to a process chamber or a process recipe for which a transfer model is to be developed using method 500. In some implementations, the source domain and the target domain can be of a certain (e.g., same or similar) type. A type can refers to a particular characteristic of a domain (e.g., type of process chamber, type of recipe, type of recipe performed on a process chamber, etc.). For example, both the source domain and the target domain can be the same type in that both process chambers perform a deposition process according to the same recipe. In another example, a first etch chamber can be the first domain that the machine-learning model is trained on, while the transfer model is generated by method 500 from data for a second etch chamber. Both process chambers are the same type in that both process chambers are etch chambers.

At operation 510, processing logic obtains trace data related to the source domain (referred to as source trace data). In some implementations, the source trace data can include trace data used to train the machine-learning model (e.g., machine-learning model 190). In an illustrative example, the source trace data include a set of traces (e.g., 100 traces) generated in relation with a process chamber performing a particular process recipe. Each trace of the set can relate to sensor data obtained from a particular sensor or subsystem during a respective run. In particular, a trace can reflect sensor values measured during the time period of a particular run.

In some implementations, the source trace data can include traces from normal runs and/or simulated runs. Normal run data (trace data from a normal run) can include trace data obtained while the processing chamber runs the process recipe under normal operating conditions. Simulated run data (trace data from a normal run) can include trace data obtained from runs that had artificial data added to them to simulate an error (e.g., on a component of a process chamber, such as the chamber pressure). In an illustrative example, for trace data obtained from 100 runs, runs 1-50 can be normal runs and runs 51-100 can include simulated runs.

At operation 520, processing logic generates fundamental data from the source trace data. Fundamental data refers to the normal or expected signals or patterns obtained from the source trace data. In some implementations, fundamental data refer to the data remaining after the removal of abnormal data (referred to as residual data), such as, for example, noise data, error data, anomalous data, outlier data, etc. The fundamental data can be expressed by a single trace generated from the set of traces. As such, the fundamental data can be considered steady-state data obtained from the set of traces.

In some implementations, to generate the fundamental data (e.g., the source fundamental trace), the processing logic can determine an average value of the sensor values for each time slice during the runtime of a recipe. For example, each time slice can be one second (e.g., between 0-1 seconds of the runtime of the recipe, between 1-2 seconds of the runtime of the recipe, etc.). The processing logic can average the sensor values of the set of 100 traces for each time slice of the recipe. The resulting averages can be the fundamental data. In some implementation, the process logic can identify abnormal data and remove the abnormal data from the dataset used to generate the fundamental data. For example, the processing logic can identify a spike or drip in the sensor values that does not correlate to sensor data in other traces of the set. The processing logic can then classify this data as abnormal (e.g., residual data) and remove the corresponding values from the values used to generate the fundamental data.

At operation 530, processing logic obtains trace data related to the target domain (referred to as target trace data). In some implementations, the target trace data can include trace data from prior process runs related to the target domain (e.g., historical trace data). In an illustrative example, the target trace data include a set of traces (e.g., 100 traces) generated in relation with a process chamber performing a particular process recipe. In some implementations, the target trace data can include traces from normal runs and/or simulated runs. In an illustrative example, for target trace data obtained from 100 runs, runs 1-50 can be normal runs and runs 51-100 can include simulated runs.

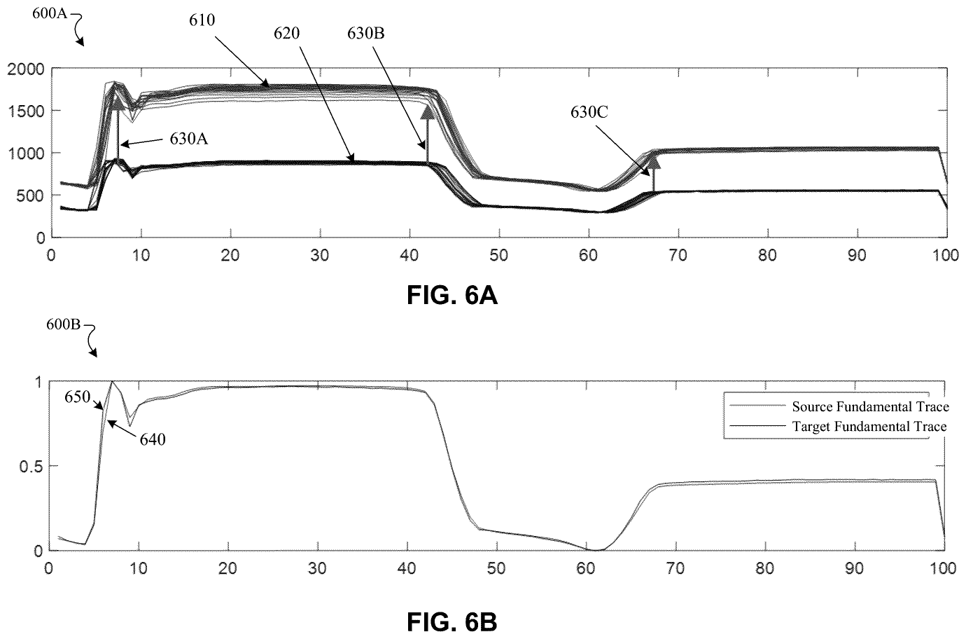

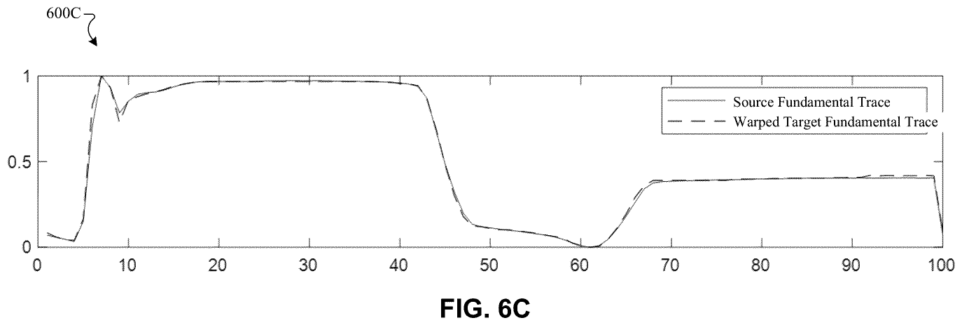

FIGS. 6A-6C are a set of graphs illustrating a set of traces data, according to aspects of the present disclosure. FIG. 6A illustrates graph 600A showing a set of source traces 610 and a set of target traces 620. The x-axis reflects time while the y-axis reflects sensor data (e.g., pressure values, temperature values, etc.) obtained from a respective process chamber related to a respective domain (e.g., a source process chamber, a target process chamber, a process chamber running a source recipe, a process chamber running a target recipe, etc.). Tie points 630A-630C will be discussed below in relation to operation 550.

Returning to FIG. 5, at operation 540, processing logic generates fundamental data from the target trace data. In some implementations, the target fundamental data is a single fundamental trace referred to as the target fundamental trace. The processing logic can use methods similar to those described in reference to operation 520.

FIG. 6B illustrates graph 600B showing an example source fundamental trace 640 and a target fundamental trace 650. The x-axis reflects time while the y-axis reflects an arbitrary value between 0 and 1. This arbitrary value can be reflective of a scaled value. For example, the value obtained from the trace data shown in FIG. 6A can be scaled such that they are expressed between the scaled values of 0 and 1. Each of the source fundamental trace and the target fundamental trace can be assigned a respective scaling factor such that the lowest value of the trace is positioned at y=0, and the highest value of one or both of the traces is positioned at y=0.

Returning to FIG. 5, at operation 550, processing logic generates a transfer map based on the source fundamental data and the target fundamental data. The transfer map can indicate the point-to-point relationship between the source fundamental trace and the target fundamental trace. In some implementations, the point-to-point relationship can be based on respective time slices (e.g., the three second mark of the source fundamental trace is correlated to the three second mark of the target fundamental trace). In some implementations, the point-to-point relationship can be based on tie point (e.g., tie point 630A-630B). A tie point is a location is a location one fundamental trace (e.g., one the source fundamental trace or the target fundamental trace) having similar features as the other fundamental trace. For example, a tie point can a peak, a valley, a drop, a rise, a slope, a flat portion, or any combination thereof. As shown in FIG. 6A, tie point 630A reflects a similar peak between both fundamental traces, tie point 630B reflects a similar drop between both fundamental traces, and tie point 630C reflects a similar rise between both fundamental traces.

Processing logic can use the transfer map to transfer data (e.g., values) from the target domain to the source domain without changing data in the source domain. To generate the transfer map, the processing logic can first scale the source fundamental trace and the target fundamental trace. The processing logic can then align the source fundamental trace and the target fundamental trace based on the Euclidean distances between corresponding value of the source fundamental trace and the target fundamental trace (e.g., respective values on each time slice).

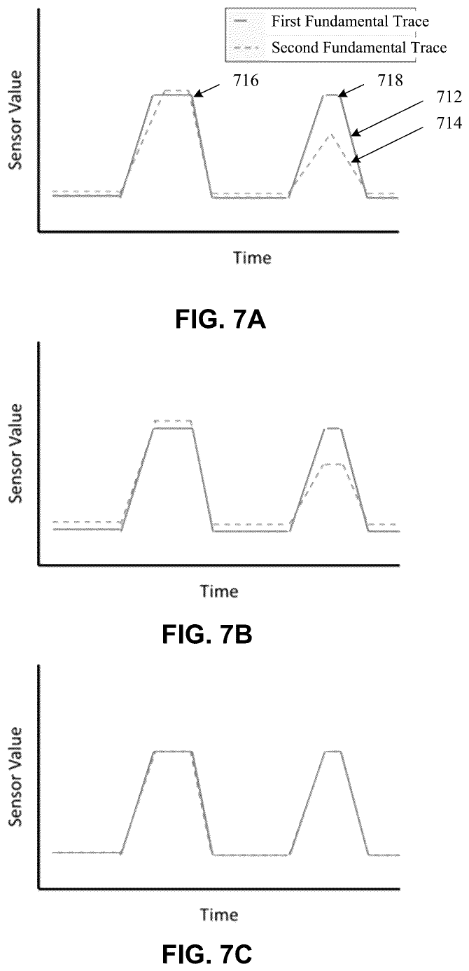

In some implementations, during generation of the transfer map, the processing logic can apply one or more scaling techniques to different features (or at specific locations) in the trace data. For example, in instances where the differences between the first fundamental trace and the second fundamental trace are related to a specific feature(s) in the trace data, the processing logic can apply a feature-based vertical scaling technique. FIGS. 7A-7C are a set of graphs illustrating the feature-based vertical scaling technique, according to aspects of the present disclosure. In particular, FIGS. 7A-7C show the first fundamental trace 712 and second fundamental trace 714 having two plateaus 716, 718 where the positioning in time is similar between the first and second fundamental traces 712, 714. The height of the first plateau 716 may be similar between the two fundamental traces 712, 714 while the height of the second plateau may not be similar. In situations of this type, the processing logic can perform feature-based vertical scaling in which the transfer map captures and addresses the different vertical mapping requirements of these two features. FIGS. 7A-7C illustrates how a transfer map might align the fundamental traces (FIG. 7A) without feature-based vertical scaling (FIG. 7B) and with feature-based vertical scaling (FIG. 7C). The values in generating these alignments can be stored and used to generate a warp map.

The processing logic can then generate a warp map. The warp map can indicate the warping relationship from the source fundamental trace to the target fundamental trace. In particular, the warp map can indicate how in which direction does each value of the target fundamental trace deviated from the respective value of the source fundamental trace. For example, if at 1 second, the corresponding sensor value on the source fundamental trace is 3, and the corresponding sensor value on the target fundamental trace is 4, then the warp map would indicate a warp value of 1.

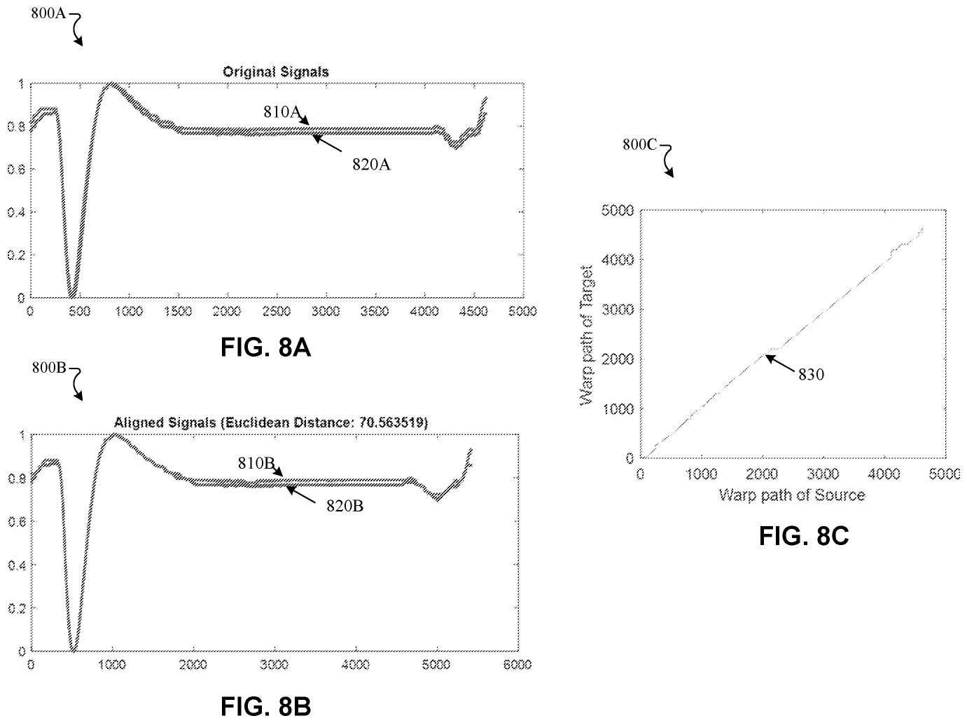

FIGS. 8A-8C are a set of graphs illustrating the alignment and warping relationship between a source fundamental trace and a target fundamental trace, according to aspects of the present disclosure. FIG. 8A illustrates graph 800A showing an example source fundamental trace 810A and a target fundamental trace 820A. The x-axis reflects time while the y-axis reflects a scaling value between 0 and 1. Source fundamental trace 810A and a target fundamental trace 820A are original trace values that are scaled. FIG. 8B illustrates graph 800B showing an example source fundamental trace 810B and a target fundamental trace 820B. The x-axis reflects time while the y-axis reflects a scaling value between 0 and 1. Source fundamental trace 810B and a target fundamental trace 820B are aligned. FIG. 8C illustrates graph 800C showing a warp map. The x-axis reflects the warp path of the source fundamental trace while the y-axis reflects the warp path of the target fundamental trace. Line 830 indicates which way the warping occurs.

Returning to operation 550 of FIG. 5, the processing logic can then warp the scaled target fundamental data. In some implementations, the processing logic can, per time slice, determine an offset value such that the target fundamental data lines up with the source fundamental data. The offset value can be a value offset in the x-direction on a graph, in the y-direction on a graph, or any combination thereof. The processing logic can then offset the data points on the target fundamental trace, based on the offset values, to generate a warped target fundamental trace. The warped target fundamental trace can be such that it overlays on the source fundamental trace. The offset values can be part of the transfer map. FIG. 6C illustrates graph 600C showing an example source fundamental trace and a warped target fundamental trace.

The processing logic can then recover the source fundamental trace and the warped target fundamental trace back to their original scale. For example, the processing logic can apply negative scaling values of the scaling value used to initially scale the traces.

In some implementations, one or more steps described in operation 550 can be performed using a transfer function. A transfer function is a mathematical function that models a system's output for each possible input. For example, this function can be a two-dimensional graph of an independent scalar input versus the dependent scalar output, called a transfer curve or characteristic curve.

At operation 560, processing logic generates a transfer model based on the transfer map. In some implementations, the transfer model can be generated based on the offset values of the transfer map. In some implementations, in some implementations, the transfer model can be generated using a transfer function. A transfer function is a mathematical function that models a system's output for each possible input. For example, this function can be a two-dimensional graph of an independent scalar input versus the dependent scalar output, called a transfer curve or characteristic curve. In an implementation, the processing logic can apply a shape-based transfer function based on the transfer map. The shape-based transfer function can find the optimal transfer path from the target domain to the source domain by using the transfer map to look at the shape difference between the fundamental traces.

In some implementations, the transfer model can be configured to receive current trace data associated with the target domain. The transfer model can then modify the current trace data, for each time slice, based on the respective offset values to generate transferred target traces. The transferred target traces can then be input into the machine learning model to generate analytic and/or predictive data. In an illustrative example, the transfer map can indicate that sensor values from the target fundamental trace are lower than respective sensor values from the source fundamental trace by 3 units, then the transfer model can modify current trace data by increasing the respective sensor values by 3 units. These transferred target traces can then be input into the machine-learning model and the model can output predictive and/or analytic results.

In some implementations, the transfer model can be applied to the machine-learning model to generate a modified machine-learning model. The modified machine-learning model can receive, as input data, current trace data associated with the target domain, and generate analytic and/or predictive data for the target domain. In one implementation, the process logic can retrain or update the machine-learning model (via predictive system 160) using the transfer model. The updated machine-learning model can then be used to generate predictive and/or analytic data for the target domain. By updating the machine-learning model rather than training a new machine-learning model for the target domain, considerable computational and time resources can be saved.

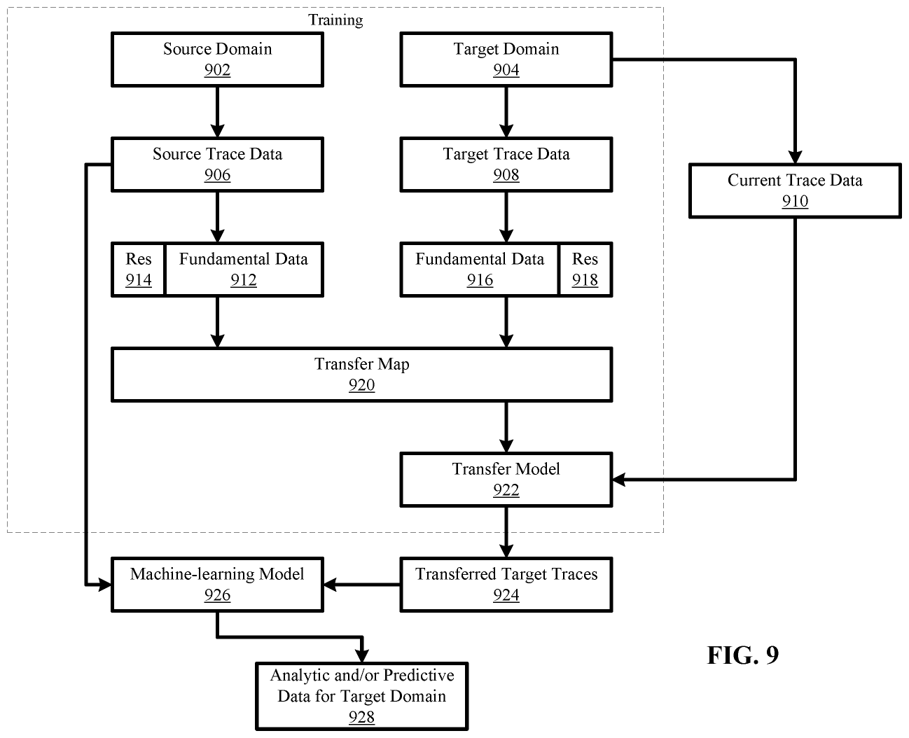

FIG. 9 is a diagram of the framework for applying a transfer model on current trace data related to a target domain to generate predictive data using a machine-learning model trained for a source domain, according to aspects of the present disclosure. Source domain 902 can refer to a process chamber or a process recipe for which a machine-learning model was generated. For example, using source trace data 906, machine-learning model 926 can be generated for source domain 902 by using source trace data 906 as training data for generating the machine-learning model 926. In some implementations, machine-learning model 926 can be trained using method 400 of FIG. 4. To train transfer model 922, source trace data 906 can be processed to extract source fundamental trace data 912 and source residual data 914. Similarly, target trace data 908 (from target domain 904) can be processed to extract target fundamental trace data 916 and target residual data 918. The source fundamental trace data and the target fundamental trace data can be used to generate transfer map 920, which can be used to train transfer model 922. During operation, current trace data 910 from target domain 904 can be fed into transfer model 922, which can output transferred target traces 924. The transferred target traces can then be input into machine-learning model 926 to generate analytic and/or predictive data 928.

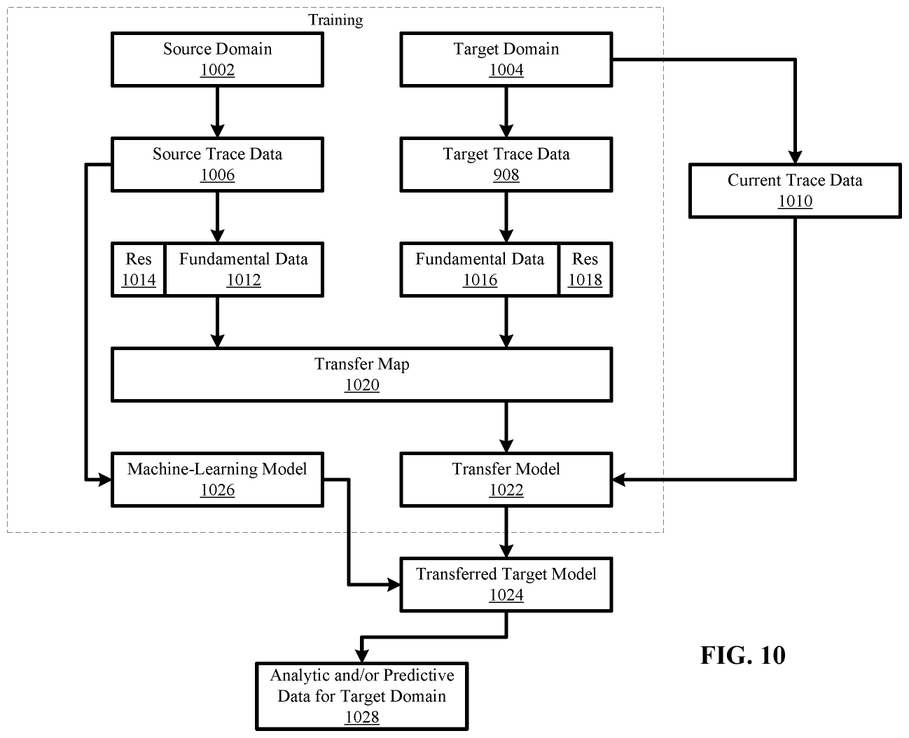

FIG. 10 is a diagram of the framework for applying a transfer model to a machine-learning model trained for a source domain, according to aspects of the present disclosure. Source domain 1002 can refer to a process chamber or a process recipe for which machine-learning model 1026 was trained. To train transfer model 1022, source trace data 1006 can be processed to extract source fundamental trace data 1012 and source residual data 1014. Similarly, target trace data 1008 (from target domain 1004) can be processed to extract target fundamental trace data 1016 and target residual data 1018. The source fundamental trace data and the target fundamental trace data can be used to generate transfer map 1020, which can be used to train transfer model 1022. The transfer model 1022 can be used to generate transferred target model 1024 by modifying or retraining machine-learning model 1026. During operation, current trace data 1010 from target domain 1004 can be fed into transferred target model 1024, which can generate analytic and/or predictive data 1028.

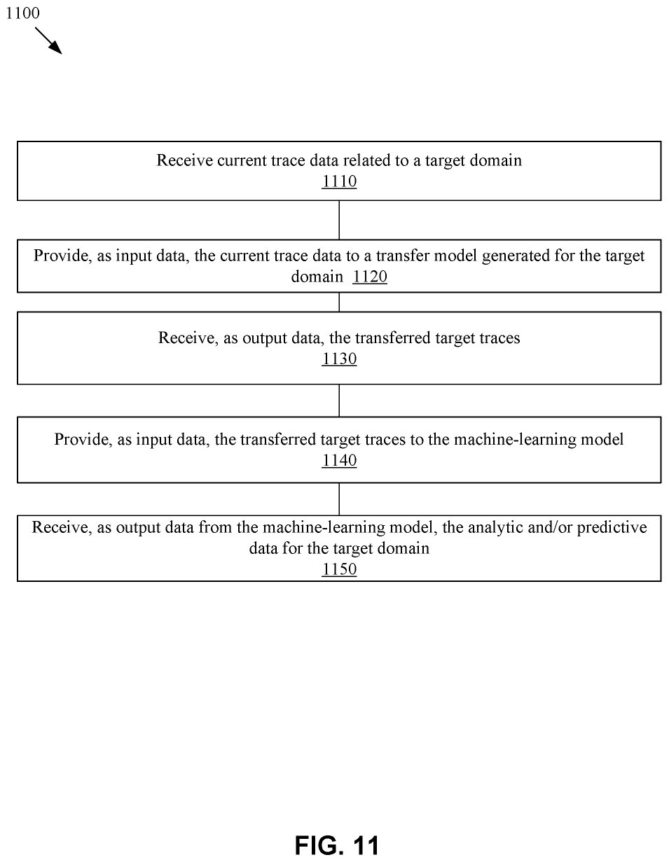

FIG. 11 is a flow chart of a method 1100 for applying a transfer model to current trace data related to a target domain, according to aspects of the present disclosure. Method 1100 is performed by processing logic that can include hardware (circuitry, dedicated logic, etc.), software (such as is run on a general-purpose computer system or a dedicated machine), firmware, or some combination thereof. In one implementation, method 1100 can be performed by a computer system, such as computer system architecture 100 of FIG. 1. In other or similar implementations, one or more operations of method 1100 can be performed by one or more other machines not depicted in the figures. In some aspects, one or more operations of method 1100 can be performed by client device 110, model generation system 150, server machine 170, server machine 180, and/or predictive server 195.

At operation 1110, processing logic receives current trace data related to a target domain.

At operation 1120, processing logic provides, as input data, the current trace data to a transfer model generated for the target domain. The transfer model can be generated (and/or trained) using method 500 of FIG. 5. In some implementations, the transfer model enables a source machine-learning model to be reused on data (e.g., the current trace data) received from the target domain. For example, the transfer model can convert the trace data related to the target domain such that it can be used with the source machine-learning model.

At operation 1130, processing logic receives, as output data, the transferred target traces.

At operation 1140, processing logic provides, as input data, the transferred target traces to the machine-learning model.

At operation 1150, processing logic receives, as output data from the machine-learning model, the analytic and/or predictive data for the target domain. In some implementation, processing logic can perform one or more corrective action to the target domain (e.g., the process chamber related to the target domain, the process recipe related to the target domain, etc.) based on the analytic and/or predictive data.

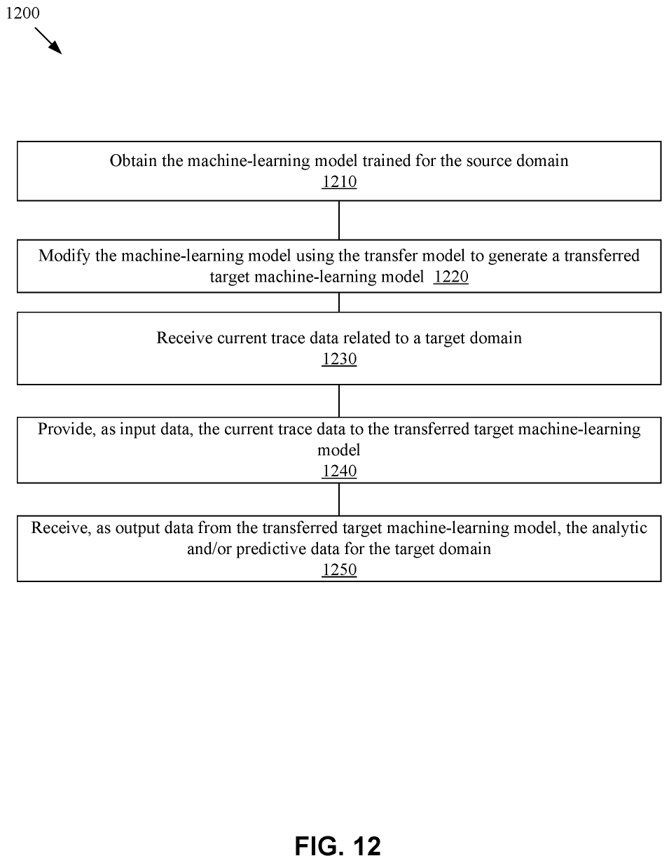

FIG. 12 is a flow chart of a method 1200 for applying a transfer model to a machine-learning model trained for a source domain, according to aspects of the present disclosure. Method 1200 is performed by processing logic that can include hardware (circuitry, dedicated logic, etc.), software (such as is run on a general-purpose computer system or a dedicated machine), firmware, or some combination thereof. In one implementation, method 1200 can be performed by a computer system, such as computer system architecture 100 of FIG. 1. In other or similar implementations, one or more operations of method 1200 can be performed by one or more other machines not depicted in the figures. In some aspects, one or more operations of method 1200 can be performed by client device 110, model generation system 150, server machine 170, server machine 180, and/or predictive server 195.

At operation 1210, processing logic obtains the machine-learning model trained for the source domain. The machine-learning model can be generated using method 400.

At operation 1220, processing logic modifies the machine-learning model using the transfer model to generate a transferred target machine-learning model. In some implementations, to modify the machine-learning model, processing logic can train a new machine-learning model (or retrain the machine-learning model) using components of the machine-learning model and the transfer model. In another implementation, the processing logic can adjust one or more features of the machine-learning model using the transfer model.

At operation 1230, processing logic receives current trace data related to a target domain.

At operation 1240, processing logic provides, as input data, the current trace data to the transferred target machine-learning model (e.g., the retrained machine-learning model).

At operation 1250, processing logic receives, as output data from the transferred target machine-learning model, the analytic and/or predictive data for the target domain. In some implementation, processing logic can perform one or more corrective action to the target domain (e.g., the process chamber related to the target domain, the process recipe related to the target domain, etc.) based on the analytic and/or predictive data.

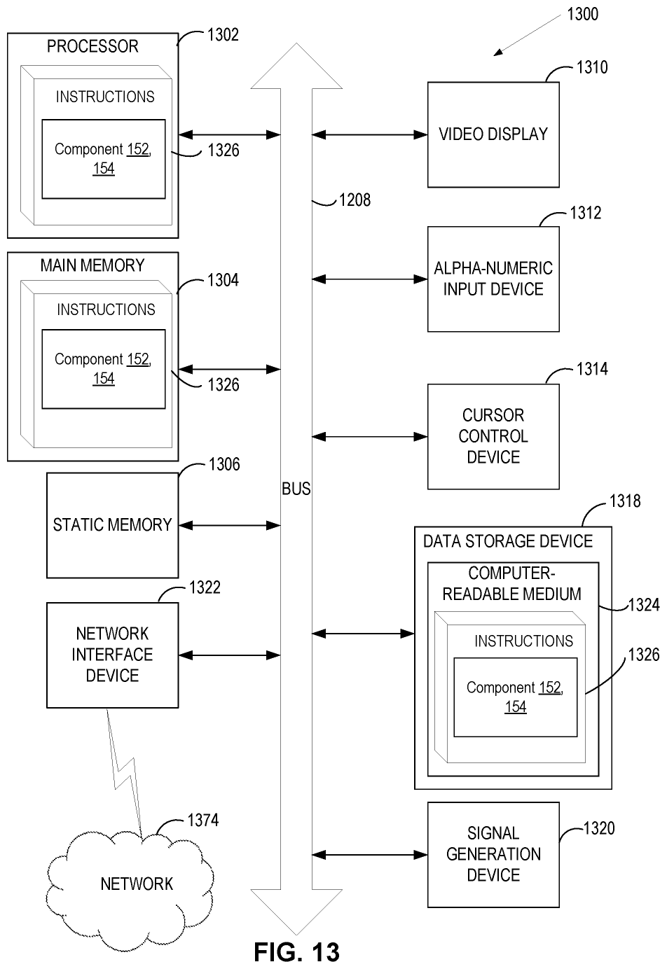

FIG. 13 is a block diagram illustrating a computer system 1300, according to certain implementations. In some implementations, computer system 1300 can be connected (e.g., via a network, such as a Local Area Network (LAN), an intranet, an extranet, or the Internet) to other computer systems. Computer system 1300 can operate in the capacity of a server or a client computer in a client-server environment, or as a peer computer in a peer-to-peer or distributed network environment. Computer system 1300 can be provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein.

In a further aspect, the computer system 1300 can include a processing device 1302, a volatile memory 1304 (e.g., Random Access Memory (RAM)), a non-volatile memory 1306 (e.g., Read-Only Memory (ROM) or Electrically-Erasable Programmable ROM (EEPROM)), and a data storage device 1316, which can communicate with each other via a bus 1308.

Processing device 1302 can be provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

Computer system 1300 can further include a network interface device 1322 (e.g., coupled to network 1374). Computer system 1300 also can include a video display unit 1310 (e.g., an LCD), an alphanumeric input device 1312 (e.g., a keyboard), a cursor control device 1314 (e.g., a mouse), and a signal generation device 1320.

In some implementations, data storage device 1316 can include a non-transitory computer-readable storage medium 1324 on which can store instructions 1326 encoding any one or more of the methods or functions described herein, including instructions encoding components of FIG. 1 (e.g., components 152, 154, etc.) and for implementing methods described herein.

Instructions 1326 can also reside, completely or partially, within volatile memory 1304 and/or within processing device 1302 during execution thereof by computer system 1300, hence, volatile memory 1304 and processing device 1302 can also constitute machine-readable storage media.

While computer-readable storage medium 1324 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

The methods, components, and features described herein can be implemented by discrete hardware components or can be integrated in the functionality of other hardware components such as ASICS, FPGAs, DSPs or similar devices. In addition, the methods, components, and features can be implemented by firmware modules or functional circuitry within hardware devices. Further, the methods, components, and features can be implemented in any combination of hardware devices and computer program components, or in computer programs.

Unless specifically stated otherwise, terms such as “receiving,” “performing,” “providing,” “obtaining,” “causing,” “accessing,” “determining,” “adding,” “using,” “training,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. Also, the terms “first,” “second,” “third,” “fourth,” etc. as used herein are meant as labels to distinguish among different elements and can not have an ordinal meaning according to their numerical designation.

Examples described herein also relate to an apparatus for performing the methods described herein. This apparatus can be specially constructed for performing the methods described herein, or it can include a general purpose computer system selectively programmed by a computer program stored in the computer system. Such a computer program can be stored in a computer-readable tangible storage medium.

The methods and illustrative examples described herein are not inherently related to any particular computer or other apparatus. Various general purpose systems can be used in accordance with the teachings described herein, or it can prove convenient to construct more specialized apparatus to perform methods described herein and/or each of their individual functions, routines, subroutines, or operations. Examples of the structure for a variety of these systems are set forth in the description above.

The above description is intended to be illustrative, and not restrictive. Although the present disclosure has been described with references to specific illustrative examples and implementations, it will be recognized that the present disclosure is not limited to the examples and implementations described. The scope of the disclosure should be determined with reference to the following claims, along with the full scope of equivalents to which the claims are entitled.

1. A method, comprising:
identifying a machine-learning model trained to generate analytic or predictive data for a first substrate processing domain associated with a type of substrate processing system;
obtaining first trace data pertaining to the first substrate processing domain, the first trace data used to train the machine-learning model;
generating a transfer model for a second substrate processing domain associated with the type of substrate processing system, wherein the transfer model is generated based on the first trace data pertaining to the first substrate processing domain and second trace data pertaining to the second substrate processing domain; and
modifying, using the transfer model, at least one of the machine-learning model or current trace data associated with the second substrate processing domain to enable the machine-learning model to generate analytic or predictive data associated with the second substrate processing domain.

2. The method of claim 1, wherein the first substrate processing domain comprises a first process chamber and the second substrate processing domain comprises a second process chamber, wherein the first process chamber and the second process chamber are a same type of process chamber.

3. The method of claim 1, wherein the first substrate processing domain comprises a first process recipe and the second substrate processing domain comprise a second process recipe.

4. The method of claim 1, wherein the first trace data comprises a first set of traces associated with the first substrate processing domain and the second trace data comprises a second set of traces associated with the second substrate processing domain.

5. The method of claim 4, further comprising:
generating, from the first set of traces, a first fundamental trace; and
generating, from the second set of traces, a second fundamental trace.

6. The method of claim 5, further comprising:
generating, based on the first fundamental trace and the second fundamental trace, a transfer map reflecting a relationship between the first fundamental trace and the second fundamental trace.

7. The method of claim 6, where the transfer map provides feature-based scaling in reflecting the relationship between the first fundamental trace and second fundamental trace.

8. The method of claim 6, wherein the transfer map is used to generate the transfer model.

9. The method of claim 1, further comprising:
providing, as input to the transfer model, current trace data pertaining to the second substrate processing domain;
obtaining one or more first output values of the transfer model;
providing, as input to the machine-learning model, the one or more first output values; and
obtaining one or more second output values of the machine learning model, the one or more second output values reflecting the analytic or predictive data associated with the second substrate processing domain.

10. The method of claim 9, further comprising:
performing a corrective action based on the one or more second output values of the machine-learning model.

11. The method of claim 1, further comprising:
retraining the machine-learning model using the transfer model;
providing, as input to the retrained machine-learning model, current trace data pertaining to the second substrate processing domain; and
obtaining one or more output values of the retrained machine-learning model reflecting the analytic or predictive data associated with the second substrate processing domain.

12. The method of claim 11, further comprising:
performing a corrective action based on the one or more output values of the machine-learning model.

13. A system, comprising:
a memory device; and
a processing device, operatively coupled to the memory device, to perform operations comprising:
identifying a machine-learning model trained to generate analytic or predictive data for a first substrate processing domain associated with a type of substrate processing system;
obtaining first trace data pertaining to the first substrate processing domain, the first trace data used to train the machine-learning model;
generating a transfer model for a second substrate processing domain associated with the type of substrate processing system, wherein the transfer model is generated based on the first trace data pertaining to the first substrate processing domain and second trace data pertaining to the second substrate processing domain; and
modifying, using the transfer model, at least one of the machine-learning model or current trace data associated with the second substrate processing domain to enable the machine-learning model to generate analytic or predictive data associated with the second substrate processing domain.

14. The system of claim 13, wherein the first trace data comprises a first set of traces associated with the first substrate processing domain and the second trace data comprises a second set of traces associated with the second substrate processing domain.

15. The system of claim 14, wherein the operations further comprise:
generating, from the first set of traces, a first fundamental trace; and
generating, from the second set of traces, a second fundamental trace.

16. The system of claim 15, wherein the operations further comprise:
generating, based on the first fundamental trace and the second fundamental trace, a transfer map reflecting a relationship between the first fundamental trace and the second fundamental trace.

17. The system of claim 13, wherein the operations further comprise:
providing, as input to the transfer model, current trace data pertaining to the second substrate processing domain;
obtaining one or more first output values of the transfer model;
providing, as input to the machine-learning model, the one or more first output values; and
obtaining one or more second output values of the machine learning model, the one or more second output values reflecting the analytic or predictive data associated with the second substrate processing domain.

18. The system of claim 11, wherein the operations further comprise:
retraining the machine-learning model using the transfer model;
providing, as input to the retrained machine-learning model, current trace data pertaining to the second substrate processing domain; and
obtaining one or more output values of the retrained machine-learning model reflecting the analytic or predictive data associated with the second substrate processing domain.

19. The system of claim 18, wherein the operations further comprise:
performing a corrective action based on the one or more output values.

20. A method, comprising:
providing, as input to a transfer model, current trace data associated with a target substrate processing domain, wherein the transfer model is generated based on historical trace data associated with the target substrate processing domain and historical trace data associated with a source substrate processing domain, wherein the source substrate processing domain and the target substrate processing domain are both associated with a type of substrate processing system;
obtaining one or more first output values of the transfer model reflective of the current trace data modified by a set of offset values;
providing, as input to a machine-learning model trained to generate analytic or predictive data for the source substrate processing domain, the one or more first output values from the transfer model; and
obtaining one or more second output values of the machine learning model, the one or more second output values representing analytic or predictive data associated with the target substrate processing domain.

21. The method of claim 20, further comprising:
performing a corrective action based on the one or more second output values of the machine-learning model.

22. A method, comprising:
retraining a machine-learning model using a transfer model, wherein the transfer model is generated based on historical trace data associated with a target substrate processing domain and historical trace data associated with a source substrate processing domain, wherein the source substrate processing domain and the target substrate processing domain are associated with a type of substrate processing system, wherein the machine-learning model is trained to generate analytic or predictive data for the source substrate processing domain;
providing, as input to the retrained machine-learning model, current trace data pertaining to the target substrate processing domain; and
obtaining one or more output values of the retrained machine-learning model reflecting analytic or predictive data associated with the target substrate processing domain.

23. The method of claim 22, further comprising:
performing a corrective action based on the one or more second output values of the modified machine-learning model.
